(19) United States
(12) Patent Application Publication
(10) Pub. No.: US 2011/0180782 A1
(43) Pub. Date: Jul. 28, 2011

(54) Light-Emitting Devices

(75) Inventors: David A. Fattal, Mountain View, CA (US); Duncan Stewart, Menlo Park, CA (US)

(73) Assignee: HEWLETT-PACKARD DEVELOPMENT COMPANY, L.P., Houston, TX (US)

(21) Appl. No.: 13/002,897

(22) PCT Filed: Jul. 25, 2008
(86) PCT No.: PCT/US2008/009077

§ 371 Date: Apr. 4, 2011

(51) Int. Cl. H01L 33/06; B82Y 99/00

(52) U.S. Cl. 257/13; 257/E33.008; 977/774

(57) ABSTRACT

Various embodiments of the present invention are directed to semiconductor light-emitting devices that provide energy efficient, high-speed modulation rates in excess of 10 Gbits/sec. These devices include a light-emitting layer embedded between two relatively thicker semiconductor layers. The energy efficient, high-speed modulation rates result from the layers adjacent to the light-emitting layer being composed of semiconductor materials with electronic states that facilitate injection of carriers into the light-emitting layer for light emission when an appropriate light-emitting voltage is applied and facilitate the removal of carriers when an appropriate light-quenching voltage is applied.

### TECHNICAL FIELD

Embodiments of the present invention relate to semiconductor light-emitting devices.

### BACKGROUND

On-chip and off-chip communication has emerged as a critical issue for sustaining performance growth for the demanding, data-intensive applications for which many chips are needed. Computational bandwidth scales linearly with the growing number of transistors, but the rate at which data can be communicated across a chip using top-level metal wires is increasing at a much slower pace. In addition, the rate at which data can be communicated off-chip through pins located along the chip edge is also growing more slowly than compute bandwidth, and the energy cost of on-chip and off-chip communication significantly limits the achievable bandwidth.

Optical interconnects including optical fibers or waveguides have been proposed as an alternative to wires used in on-chip and off-chip communications. For example, a single fiber optic cable can carry terabits per second of digital information encoded in different wavelengths of light called optical signals with a capacity ranging from about 4×10⁴ to about 5×10⁴ times greater than transmitting the same information using wires (cf. 5 GHz Pentium with 200 THz optical signal at 1.5 micron wavelength). Because of the increasing interest in transmitting data in optical signals, much interest is now being paid to small scale light sources that can be modulated to generate optical signals. The light-emitting diode (“LED”) is a low cost light source that can be modulated to encode data in optical signals. Common LEDs include a depletion layer, and in some cases may include a thin undoped or intrinsic semiconductor layer, sandwiched between a p-type semiconductor layer and an n-type semiconductor layer (see e.g., S. Sze, Ch 12.3.2 of Physics of Semiconductor Devices, 2^{nd} Ed., Wiley, New York, 1981). Electrodes are attached to the p-type layer and the n-type layer. When no bias is applied to an LED, the depletion layer has a relatively low concentration of electrons in a corresponding conduction band and a relatively low concentration of vacant electronic states called “holes” in a corresponding valence band and substantially no light is emitted. The electrons and holes are called “charge carriers” or just “carriers.” In contrast, when a forward-bias operating voltage is applied across the layers, electrons are injected into the conduction band of the depletion layer, while holes are injected into the valence band of the depletion layer creating excess carriers. The electrons in the conduction band spontaneously recombine with holes in the valence band in a radiative process called “electron-hole recombination” or “recombination.” When electrons and holes recombine, photons of light are emitted with a particular wavelength. As long as an appropriate operating voltage is applied in the same forward-bias direction, nonequilibrium carrier population is maintained within the depletion layer and electrons spontaneously recombine with holes, emitting light of a particular wavelength in nearly all directions. When the bias is removed, excess carriers remaining in the depletion layer can recombine or the built-in electric field of the p-n junction can sweep the excess carriers from the depletion layer, and radiative recombination stops. The radiative recombination fall-off time is determined by the excess carrier lifetime or by the time it takes the excess carriers to drift through the depletion layer. Typically, in high-quality materials, the excess carrier lifetime is long. In some cases, therefore, excess carriers continue recombining for a period of time after the voltage is removed. Thus, the emitted optical signal may not decrease substantially for a period of time after the voltage is turned off or becomes low.

A data-encoded optical signal generated by modulating an LED is ideally composed of distinguishable high and low intensities. For example, high and low operating voltage pulses corresponding to the bits “1” and “0” can be applied to an LED to encode the same information in high and low intensities of light emitted from the LED. High intensity light emitted from an LED for a period of time can represent the bit “1,” and low intensity or no light emitted from the LED for a period of time can represent the bit “0.” In practice, however, when the operating voltage is modulated at high speeds, such as about 50 GHz, the high and low intensities of the optical signal may be indistinguishable because the LEDs can continue to emit light between applications of the operating voltage.

FIG. 1 shows a first plot 102 of a modulated, forward-bias operating voltage applied to an LED versus time, and a corresponding second plot 104 of the intensity of an optical signal emitted from the LED versus time. In plots 102 and 104, horizontal axes 106 and 108 represent time, vertical axis 110 represents the magnitude of the forward-bias operating voltage, and vertical axis 112 represents intensity of light emitted from the LED. Rectangles 114-116 represent the magnitude and duration of voltage pulses composing the modulated, forward bias, operating voltage applied to an LED, where between each pulse, the voltage is turned off. The plots 102 and 104 reveal that light is emitted from the LED with relatively constant and continuous intensities 118-120 during the time periods when the pulses 114-116 are applied. However, the plot 104 also reveals that during the time periods between pulses 114-116, the LED continues to emit light with an intensity that slowly drops off but not completely before the next pulse is applied. In particular, curved portions 122-124 represent slow relative intensity drop offs after the pulses 114-116 are turned off.

The slow relative drop off in intensity is the result of excess electrons remaining in the conduction band and holes remaining in the valence band of the depletion layer when the voltage is turned off. These electrons and holes continue to recombine in the absence of an operating voltage. In addition, because of the high modulation speed, a subsequent operating voltage pulse is applied before the excess electrons and holes have had a chance to complete recombination. Thus, high and low intensity portions of an optical signal may be indistinguishable.

Accordingly, light-emitting devices that exhibit rapid output light intensity drop off during high speed modulation are desired.

### SUMMARY

Various embodiments of the present invention are directed to semiconductor light-emitting devices that provide energy efficient, high-speed modulation rates. In one embodiment, a light-emitting device includes a light-emitting layer having a first electronic energy state and a relatively higher energy second electronic energy state. The device also includes a first layer disposed adjacent to the light-emitting layer and a second layer disposed adjacent to the light-emitting layer opposite the first layer. The first layer includes a third electronic energy state at a relatively lower energy than the second electronic energy state, and the second layer includes a fourth electronic energy state at a relatively higher energy than the first electronic energy state. When a light-emitting voltage is applied to the light-emitting device, the third and fourth electronic energy states are arranged so that electrons can combine with holes in the light-emitting layer and light is emitted. When a light-quenching voltage is applied to the light-emitting device, the energies of the third and fourth electronic energy states shift to prevent electrons from combining with holes in the light-emitting layer.

### BRIEF DESCRIPTION OF THE DRAWINGS

FIG. 1 shows a first plot of a modulated voltage applied to a light-emitting diode versus time, and a corresponding second intensity plot of an optical signal emitted from the light-emitting diode versus time.

FIG. 2 shows a plot of parabolic energy band approximation of a valence band and a conduction band for a semiconductor.

FIG. 3 shows an isometric view of a quantum well sandwiched between two relatively thicker semiconductor layers.

FIG. 4 shows a plot of two valence and conductance sub-bands associated with a quantum well.

FIG. 5 shows an energy band diagram representing a number of quantized energy levels of an exemplary quantum dot.

FIG. 6 shows two different energy band diagrams associated with different quantum dots.

FIGS. 7A-7B show isometric views of two light-emitting devices configured in accordance with embodiments of the present invention.

FIG. 8 shows a schematic representation of a light-emitting device and an associated energy band diagram configured in accordance with embodiments of the present invention.

FIG. 9 shows a plot of an energy band diagram associated with applying a light-emitting voltage to the light-emitting device shown in FIG. 8 in accordance with embodiments of the present invention.

FIG. 10 shows a plot of an energy band diagram associated with applying a light-quenching voltage to the light-emitting device shown in FIG. 8 in accordance with embodiments of the present invention.

FIG. 11 shows two plots associated with operating the light-emitting device shown in FIG. 8 in accordance with embodiments of the present invention.

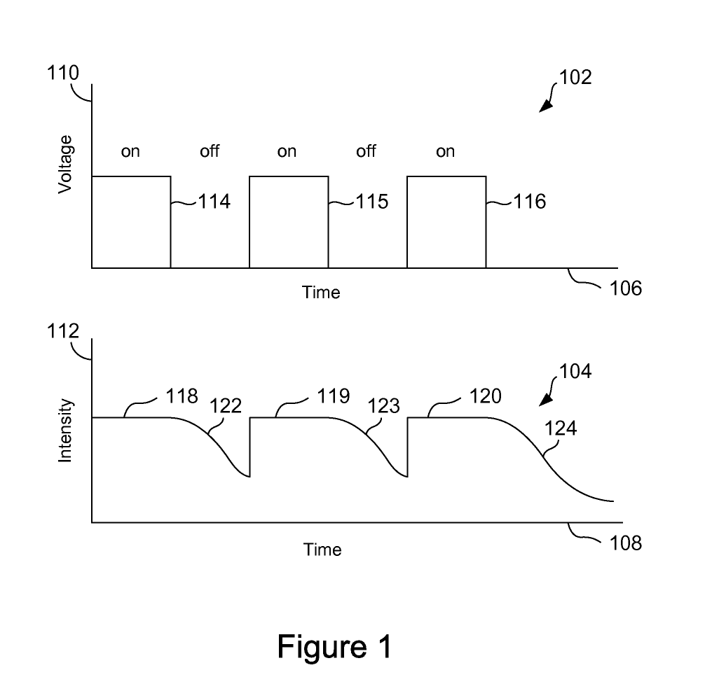

### DETAILED DESCRIPTION

Embodiments of the present invention are directed to semiconductor light-emitting devices that provide energy efficient, high-speed modulation rates on the order of 10 Gbits/sec or faster. These devices include a light-emitting layer (“LEL”) composed of either a quantum well (“QW”) or quantum dots (“QDs”) embedded in a transparent dielectric matrix. The energy efficient, high-speed modulation rates result from layers adjacent to the LEL being composed of semiconductor materials with electronic states that facilitate injection of carriers into the LEL for light emission when an appropriate light-emitting voltage is applied and facilitate the removal of carriers when an appropriate light-quenching voltage is applied.

Operation of light-emitting device embodiments are described below with reference to electronic states and energy band diagrams. In order to assist readers with the terminology used to describe various embodiments of the present invention and provide readers with an understanding of the fundamental physical principles of operation of the light-emitting devices, a general description of QWs and QDs is provided in a first subsection. Embodiments of the present invention are described in a second subsection.

### Quantum Wells and Quantum Dots

The outer electrons of semiconductor atoms in a crystal lattice are delocalized over the semiconductor crystal and the space-dependent electronic wave functions are characterized by:

ψₖ(r)=uₖ(r)exp[j(k·r)]

where uₖ (r) represents the periodicity of the semiconductor crystal lattice, k is the wavevector, k is the wavenumber (k²=k·k), and r is the electronic coordinate vector in the semiconductor. The corresponding electronic energy states E of the outer electrons are a function of k and have energy values that fall within allowed electronic energy bands.

For the sake of simplicity, only the highest energy electron filled band, the valence band, and the next higher band, the conduction band, are described using the parabolic band approximation. The valence and conduction bands are separated by an energy gap, called the electronic band gap, which contains no allowed electronic energy states for electrons to occupy.

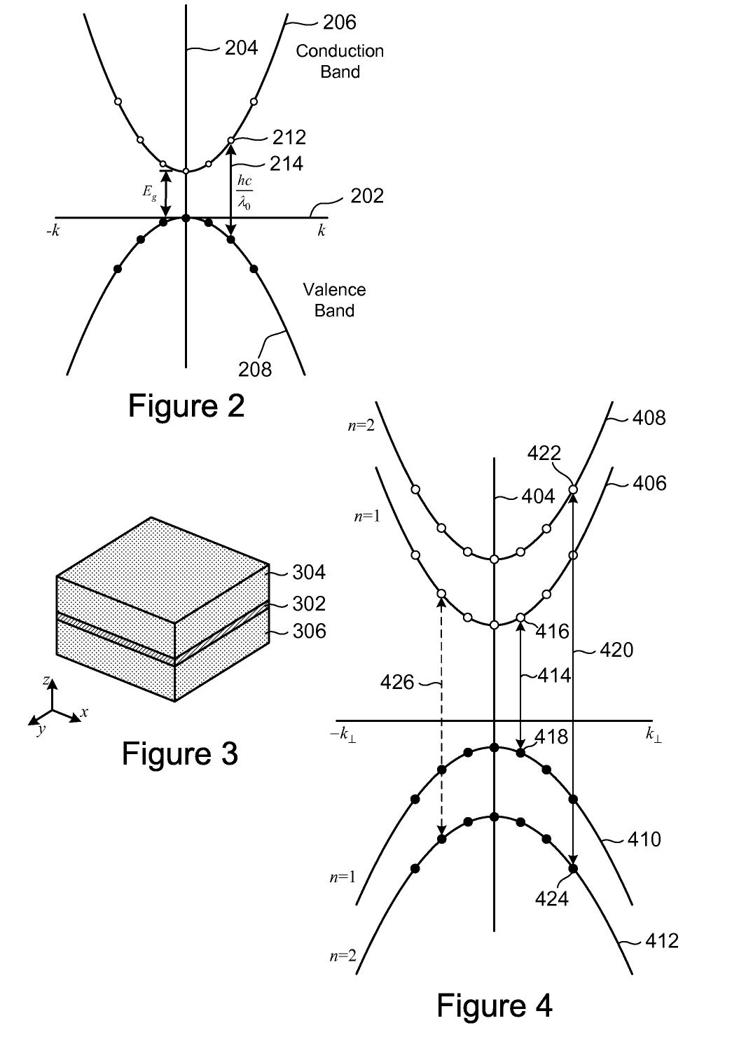

FIG. 2 shows a parabolic band approximation plot of a valence band and a conduction band for a semiconductor. Horizontal axis 202 represents the wavenumber k, vertical axis 204 represents the energy E, parabola 206 represents the conduction band, and a parabola 208 represents the valence band. The energy of the conduction band 406 can be represented by the parabolic equation:

$${E}_{c} = {E}_{g} + \frac{{ℏ}^{2} {k}^{2}}{2 {m}_{c}}$$

where m_{c}= [symbol] /(d²E_{C}/dk²) is the effective mass of an electron at the bottom of the conduction band 206, [symbol] is Plank's constant h divided by 2π, and E_{g} is the electronic band gap energy. The energy in the valence band 208 is measured from the top of the valence band downward and can be represented by the parabolic equation:

$${E}_{v} = - \frac{{ℏ}^{2} {k}^{2}}{2 {m}_{v}}$$

where m_{V}= [symbol] /(d²Eᵥ/dk²) is the effective mass of the electron at the top of the valence band 408.

Semiconductors are characterized as either direct or indirect band gap semiconductors. Direct band gap semiconductors have the valence band maximum and the conduction band minimum occurring at substantially the same wavenumber, such as the minimum of the conduction 206 and the maximum of the valence band 208 of FIG. 2. As a result, an electron in the electronic state at the conduction band minimum can recombine with a hole in the valence band maximum giving off as a photon of light with energy E_{g}. In contrast, indirect semiconductors have the valence band maximum and the conduction band minimum occurring at different wavenumbers. As a result, an electron in the electronic state at the conduction band minimum can recombine with a hole in the valence band maximum but must first undergo a momentum change as well as changing its energy. The resulting energy loss is usually given up to lattice as heat rather than emission of photons.

The one-dimensional model of the valence band 208 and the conduction band 206 can be generalized to three-dimensions by letting kₓ, k_{y}, and k_{z} be components of the electron's wavevector k and assuming that the effective mass (i.e., band curvature) is the same along the x-, y-, and z-axes. A finite-sized, rectangular parallelepiped semiconductor crystal with finite dimensions Lₓ, L_{y}, and L_{z} imposes boundary conditions on the total phase shift k·r across the crystal. Thus, the components of the wavevector are quantized as follows:

$${k}_{i} = ( \frac{2 π {l}_{i}}{{L}_{i}} )$$

where i=x, y, z, and lᵢ is an integer. Because the electronic energy is a function of the wavenumber k, the electronic energy states are quantized and represented by circles 210 in the valence band 208 and circles 212 in the conduction band 206. Filled circles represent electron filled electronic energy states and open circles represent holes or vacant electronic energy states.

The selection rule for radiative electronic transitions between the conduction band 206 and the valence band 208 is that the electronic energy states have the same wavenumber k and electron spin. In other words, the wavenumber k and the electronic spin state are unchanged for allowed electronic transitions between electronic energy states in the conduction band 206 and electronic energy states in the valence band 208. For example, as shown in FIG. 2, a directional arrow 214 represents an allowed electronic energy state transition between the electronic energy state 212 in the conduction band 206 and the electronic energy state 210 in the valence band 208 and the energy difference is given by:

$$\frac{h c}{{λ}_{0}} = {E}_{g} + ( \frac{{ℏ}^{2} {k}^{2}}{2 {m}_{r}} )$$

where mᵣ is the reduced mass given by mᵣ⁻¹=m_{c}⁻¹+mᵥ⁻¹. In order for an electron in the electronic energy state 210 to transition to the electronic energy state 212, the electron can be pumped with photons having a wavelength λ₀ or an electron can be injected into the conduction band 206 by application of an appropriate voltage to the device 200. When the electron spontaneously transitions from the electronic energy state 212 to the electronic energy state 210, a photon is emitted with a wavelength λ₀.

A QW is a relatively thin semiconductor layer having a thickness ranging from about 5 nm to about 20 nm. The QW is composed of semiconductor material with a relatively smaller electronic band gap energy E_{g}_{₁} than the electronic band gap energy E_{g}_{₂} of the two relatively thicker adjacent semiconductor layers. FIG. 3 shows an isometric view of a QW 302 sandwiched between two relatively thicker semiconductor layers 304 and 306. Because E_{g}_{₂} is greater than E_{g}_{₁}, a potential well is established for electrons at the top of the valance band of the QW 302, and a potential well is established for holes at the bottom of the conduction band of the QW 302. Due to the thinness of the QW 302, energy levels of electrons and holes exhibit quantum effects. The corresponding valence band and conduction band electron wave functions can be written as:

ψ_{c,v}(r_{⊥})=uₖ(r_{⊥})exp[j(k_{⊥}·r_{⊥})] sin(nπz/L_{z})

where uₖ (r_{⊥}) has the periodicity of the QW crystal lattice in the x,y plane, k_{⊥} is the x,y plane wavevector, and r_{⊥} is the QW coordinate vector in the x,y plane. The wave function ψ_{c,v} (r_{⊥}) satisfies the boundary condition: ψ_{c,v} equals 0 for z equal to 0 and for z equal to L_{z}. A finite-sized QW in the x,y plane imposes boundary conditions such that the total phase shift k_{⊥}·r_{⊥} across the crystal is an integer multiple of 2π and the wavevector k_{⊥} components are quantized as follows:

$${k}_{i} = ( \frac{π {l}_{i}}{{L}_{i}} )$$

where i=x, y, and lᵢ is an integer.

Within the parabolic band approximation, the energy states in the z-direction include sub-band energy states that can be written as:

$${E}_{c} = \frac{{ℏ}^{2} {k}_{⊥}^{2}}{2 {m}_{c}} + {n}^{2} \frac{{ℏ}^{2} {π}^{2}}{2 {m}_{c} {L}_{z}^{2}}$$

for the conduction band, and as:

$${E}_{v} = - ( \frac{{ℏ}^{2} {k}_{⊥}^{2}}{2 {m}_{v}} + {n}^{2} \frac{{ℏ}^{2} {π}^{2}}{2 {m}_{v} {L}_{z}^{2}} )$$

for the valence band, where n is a positive integer or quantum number corresponding to the sub-band energy states, k_{⊥} is the wavenumber (k_{⊥}²=k_{⊥}·k_{⊥}), and [symbol] π²/2m_{c,v}L_{z}² is the energy of first QW state.

FIG. 4 shows a plot of two valence and conductance sub-bands associated with a QW. Horizontal axis 402 represents the wavenumber k_{⊥}, a vertical axis 404 represents the electronic energy E, parabolas 406 and 408 represent the conduction sub-bands for n=1 and n=2, respectively, and parabolas 410 and 412 represents the valence sub-bands for n=1 and n=2, respectively. Because of the finite dimensionality of the QW 302 in the z-direction, the electronic energy states of sub-bands are quantized. Filled circles in the valence bands 410 and 412 represent electrons and open circles in the conduction bands 406 and 408 represent holes or available electronic states.

The selection rules for allowed electronic transitions between electronic states in the conduction band and electronic states in the valence band are that only transitions between the conduction bands and valence bands with the same n, k_{⊥}, and electron spin states are allowed. For example, as shown in FIG. 4, directional arrow 414 represents a first allowed electronic energy state transition between an electronic energy state 416 in the conduction band 406 and an electronic energy state 418 in the valence band 410, and a directional arrow 420 represents a second allowed electronic energy state transition between an electronic energy state 422 in the conduction band 408 and an electronic energy state 424 in the valence band 412. In contrast, a dashed-line directional arrow 426 represents an electronic energy state transition that is not allowed because the quantum numbers n associated with the conduction band 406 and the valence band 412 are different.

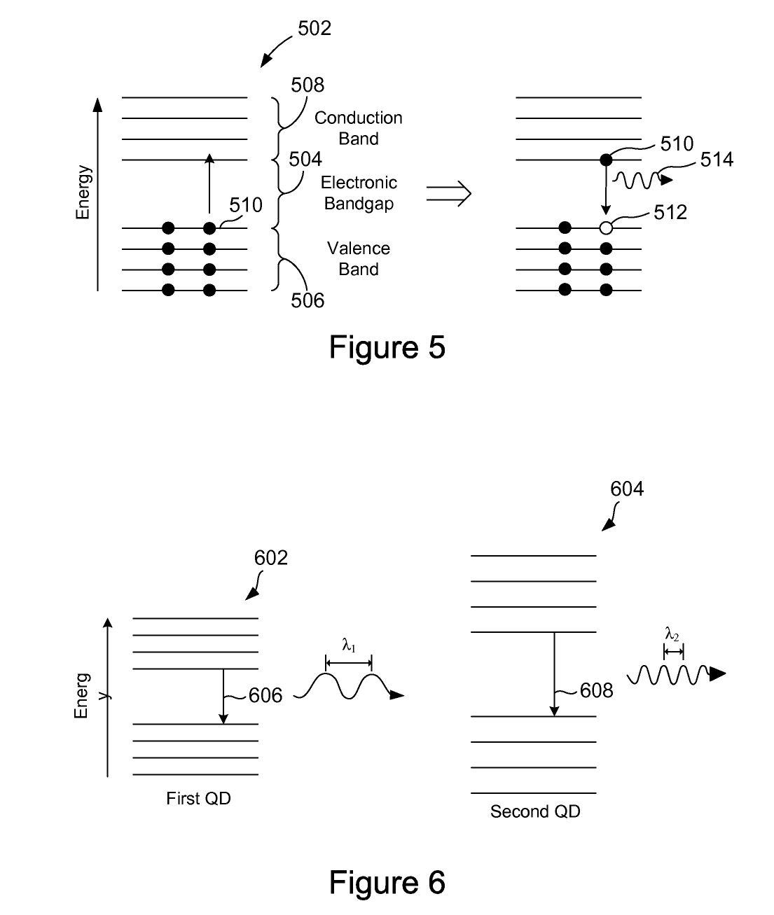

On the other hand, QDs are a semiconductor crystal that, in general, may range in diameter from about 2 to about 10 nanometers. A QD is also referred to as an “artificial atom” because the QD exhibits quantized electronic energy levels where only two electrons can occupy any one energy level. FIG. 5 shows an energy band diagram 502 representing a number of quantized energy levels of an exemplary QD. The quantized energy levels are represented by horizontal lines arranged vertically in order of increasing energy. The quantized energy levels include an electronic band gap 504 separating the quantized energy levels of a valence band 506 and the quantized energy levels of a conduction band 508. FIG. 5 reveals the lowest possible electronic energy state of the QD, which occurs when pairs of electrons denoted by filled circles occupy the energy levels in the valence band 506.

Applying an appropriate electronic stimulus, such as heat, voltage, or electromagnetic radiation, to a QD can change the electronic energy state of the QD. When the magnitude of the stimulus exceeds the band gap energy, one or more electrons can be promoted into a higher energy levels in the conduction band. For example, in FIG. 5, an electron 510 that occupies an energy level in the valence band 506 absorbs the energy associated with a stimulus by jumping into an energy level in the conduction band 508 leaving a hole 512 in the valence band 506. The electron 510 remains momentarily in an energy level of the conduction band 508 before transitioning back across the electronic band gap 504 to recombine with the hole 512 in the valence band 506. The recombination process may result in the emission of electromagnetic radiation 514 corresponding to the energy lost in the transition. Typically, electrons transition from the lowest energy level of the conduction band to the highest energy level of the valence band. Because the electronic band gap is fixed for a particular QD, each time this transition occurs electromagnetic radiation of a fixed wavelength is emitted.

The wavelength of the electromagnetic radiation emitted by a QD can, however, be adjusted by changing the size or shape of the QD. FIG. 6 shows two different band diagrams associated with two QDs. Band diagram 602 shows the quantized energy levels of a first QD, and band diagram 604 shows the quantized energy levels of a smaller second QD having the same chemical composition as the first. The band diagrams 602 and 604 reveal that the energy separations between the energy levels and band gaps of the first QD are smaller than the second QD. Thus, a transition 606 results in an emission of electromagnetic radiation with a wavelength λ₁, and a transition 608 results in an emission of electromagnetic radiation with a wavelength λ₂, where λ₂<λ₁.

### EMBODIMENTS OF THE PRESENT INVENTION

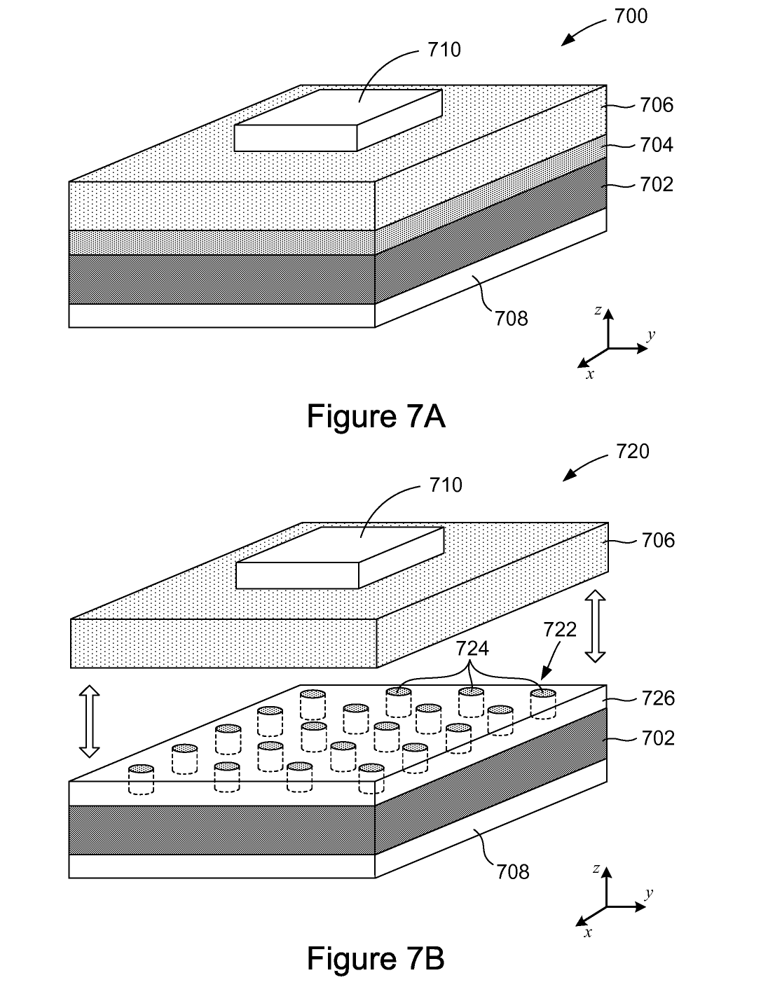

FIG. 7A shows an isometric view of a first light-emitting device 700 configured in accordance with embodiments of the present invention. The device 700 includes a first semiconductor layer 702, a quantum well light-emitting layer (“QW LEL”) 704 disposed on the first semiconductor layer 702, and a second semiconductor layer 706 disposed on the QW LEL 706. The device 700 also includes a first electrode 708 onto which the first semiconductor layer 702 is disposed and a second electrode 710 disposed on the second semiconductor layer 706.

FIG. 7B shows an exploded isometric view of a second light-emitting device 720 configured in accordance with embodiments of the present invention. The exploded view reveals that the device 720 is nearly identical to the device 700 except the QW LEL 704 of the device 700 is replaced by a QD LEL 722. The QD LEL 722 is composed of a number of QDs 724 embedded in a transparent dielectric matrix 726.

Although the devices 700 and 710 are shown in FIG. 7 as rectangular-shaped devices, in practice, the light-emitting devices of the present invention are not limited to rectangular configurations and can have many different shapes. In other words, the light-emitting device of the present invention can also be square, circular, elliptical or any other suitable shape.

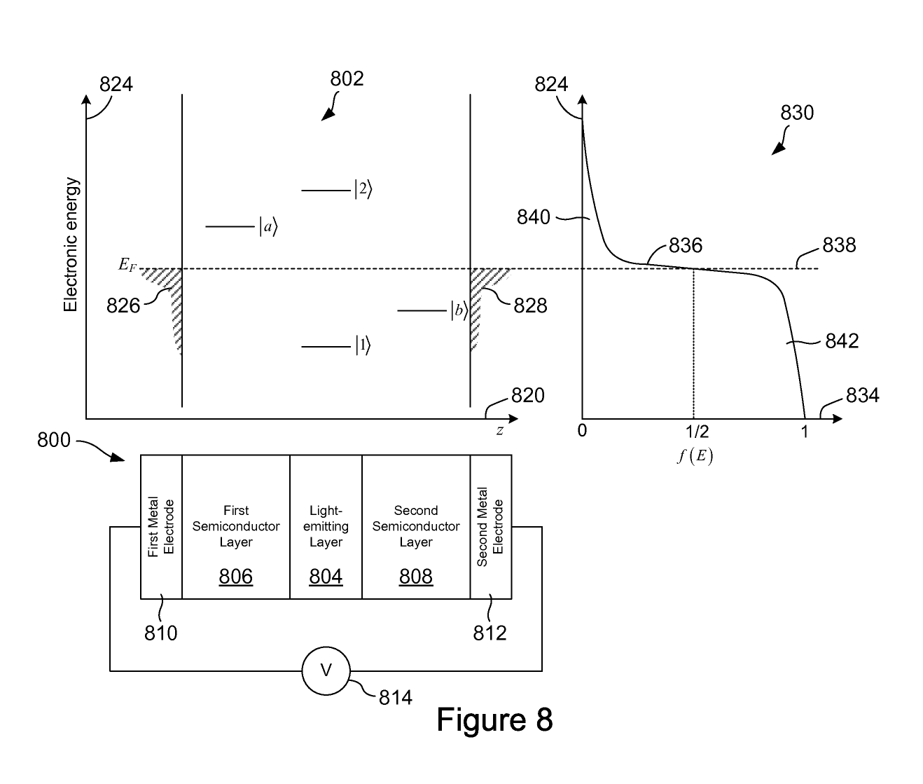

FIG. 8 shows a schematic representation of a light-emitting device 800 and an associated electronic energy band diagram 802 configured in accordance with embodiments of the present invention. The light-emitting device 800 is composed of an LEL 804 sandwiched between first and second semiconductor layers 806 and 808. A first metal electrode 810 is disposed adjacent to the first semiconductor layer 806, and a second metal electrode 812 is disposed adjacent to the second semiconductor layer 808. The electrodes 810 and 812 are electronically coupled to a voltage source 814. The light-emitting device 800 schematically represents the light-emitting devices of the present invention, such as the light-emitting devices 700 and 720. In particular, the LEL 804 represents either the QW LEL 704 or the QD LEL 722 described above.

The band diagram 802 of FIG. 8 includes a horizontal z-axis 820 running substantially parallel to the height of the device 800 and corresponding to the z-axes shown in FIGS. 7A-7B, and a vertical axis 824 representing the electronic energy. The band diagram 802 reveals the relative electronic energies associated with particular electronic energy states in the layers 804, 806, and 808 along the z-axis when no bias is applied. Shaded regions 826 and 828 represent the continuum of filled electronic energy states of the electrodes 810 and 812, respectively. A state denoted by |1 [symbol] represents a particular electronic energy state in the valence band of the LEL 804, and a state denoted by |2 [symbol] represents a particular electronic energy state in the conduction band of the LEL 804. Note that states |1 [symbol] and |2 [symbol] represent quantized electronic energy states associated with a QW and satisfy the selection rules for electron transitions between states in the sub-bands of the conduction and valence bands described above with reference to FIG. 4. The states |1 [symbol] and |2 [symbol] can also represent the energy levels of a QD as described above with reference to FIG. 5. A state denoted by |a [symbol] represents an electronic energy state residing in the first semiconductor layer 806, and a state denoted by |b [symbol] also represents an electronic energy state residing in the second semiconductor layer 808.

FIG. 8 also includes a plot 830 of a Fermi-Dirac probability distribution includes the vertical electronic energy axis 824 and a horizontal axis 834 representing probabilities ranging from 0 to 1. Curve 836 represents the Fermi-Dirac probability distribution, which is mathematically represented by:

$$f ( E ) = \frac{1}{1 + exp ( E - {E}_{F} / k T )}$$

where E represents the electronic energy of an electron, E_{F} is the Fermi level represented in FIG. 3 by a dashed line 838, k represents Boltzmann's constant, and T represents the absolute temperature of the device 800. The distribution f(E) 836 represents the probability that an electronic energy level is occupied by an electron at a particular absolute temperature T. The narrow area 840 between the energy axis 824 and the distribution f(E) 836 indicates that there is a low probability that the energy levels in the conduction band above the Fermi level 838 are occupied by electrons, and broad area 842 between the energy axis 824 and the distribution f(E) 836 indicates that there is a low probability that the energy levels in the valence band below the Fermi level 838 are empty. The general shape of the distribution f(E) 836 reveals that the likelihood of electrons occupying the energy levels above the Fermi level E_{F} 838 decreases away from the Fermi level E_{F} 838 and the likelihood of electrons occupying energy levels below the Fermi level E_{F} 838 increases away from the Fermi level E_{F} 838.

The layers 806 and 808 can be composed of elemental or compound semiconductors. Indirect elemental semiconductors include silicon (Si) and germanium (Ge), and compound semiconductors are typically III-V materials, where Roman numerals III and V represent elements in the IIIa and Va columns of the Periodic Table of the Elements. Compound semiconductors can be composed of column Ma elements, such as Aluminum (Al), Gallium (Ga), and Indium (In), in combination with column Va elements, such as Nitrogen (N), Phosphorus (P), Arsenic (As), and Antimony (Sb). Compound semiconductors can be classified according to the relative quantities of III and V elements. For example, binary semiconductor compounds include GaAs, InP, InAs, and GaP; ternary compound semiconductors include GaAs_{y}P_{1-y}, where y is greater than 0 and less than 1; and quaternary compound semiconductors include InₓGa₁₋ₓAs_{y}P_{1-y}, where both x and y independently range from greater than 0 to less than 1. Other types of suitable compound semiconductors include II-VI materials, where II and VI represent elements in the IIb and VIa columns of the periodic table. For example, CdSe, ZnSe, ZnS, and ZnO are examples of binary II-VI compound semiconductors.

The electrodes 810 and 812 can be comprised of copper, aluminum, gold, or another suitable electronically conducting metal, or the electrodes 810 and 812 can be composed of heavily doped semiconductors. In certain embodiments, the electrode 812 can be a layer of indium tin oxide (ITO) or another suitable conductive, transparent material.

In certain embodiments, the semiconductor layers 806 and 808 can be composed of substantially the same semiconductor material, while in other embodiments, the layers 806 and 808 can be composed of different semiconductor materials. One necessary condition to selecting semiconductor materials for the layers 806 and 808 is that the materials have relatively larger electronic band gap energies than the semiconductor material selected for the LEL 804. For example, in certain embodiments, the LEL 804 can be composed of GaAs, which has a band gap of approximately 1.43 eV, while the layers 806 and 808 can be composed of AlₓGaAs₁₋ₓ, where x ranges from 0 to 1, and the bang gap energies of the layers 806 and 808 correspondingly range from approximately 1.43 eV to 2.16 eV. In other embodiments, the LEL 804 can be composed of InAs, which has a band gap of approximately 0.36 eV, while the layers 806 and 808 can be composed of In₁₋ₓGaₓAs, where x ranges from 0 to 1, and the band gap energies of the layers 806 and 808 correspondingly range from approximately 0.36 eV to 1.43 eV. Note that because the layers 806 and 808 can be composed of different semiconductor materials, the parameter x in the above described examples does not have to be the same for the layers 806 and 808.

The states |a [symbol] and |b [symbol] can be produced in two ways. The first way includes doping the layer 806 with an appropriate p-type electron acceptor impurity that introduces an empty state |a [symbol] into the band gap of the first semiconductor 806 and doping the layer 808 with an n-type electron donor impurity that introduces a filled state |b [symbol] into the band gap of the second semiconductor 808. In other words, appropriate selection of the corresponding p-type and n-type impurities produces states |a [symbol] and |b [symbol] that are electronically isolated from other electronic energy states in the valence and conduction bands of the layers 806 and 808, respectively. The second way includes heavily doping the layer 806 with a p-type impurity that introduces an empty state |a [symbol] near the top of the valence band of the semiconductor layer 806 and heavily doping the layer 808 with an n-type impurity that introduces a filled state |b [symbol] near the top of the valence band of the semiconductor layer 808. Either way, as shown in FIG. 8, the p-type impurity and semiconductor material of the layer 806 are selected so that the state |a [symbol] is relatively lower in electronic energy than the state |2 [symbol] and the n-type impurity and semiconductor material of the layer 808 are selected so that the state |b [symbol] is relatively higher in electronic energy than the state |1 [symbol] . Selecting impurities and semiconductor materials in this manner prevents electrons from entering the state |2 [symbol] from the adjacent semiconductor 806 and holes from entering the state |1 [symbol] from the adjacent semiconductor 808 and combining to generate photons of light with energy substantially equal to the energy difference between the states |2 [symbol] and |1 [symbol] .

Applying an appropriate light-emitting voltage V_{EMIT} from the voltage source 814 to the device 800 generates photons corresponding to the difference in energy between the states |2 [symbol] and |1 [symbol] . The light-emitting voltage V_{EMIT} is a reverse bias that injects electrons into the first semiconductor 806 and injects holes into (i.e., removes electrons from) the second semiconductor 808.

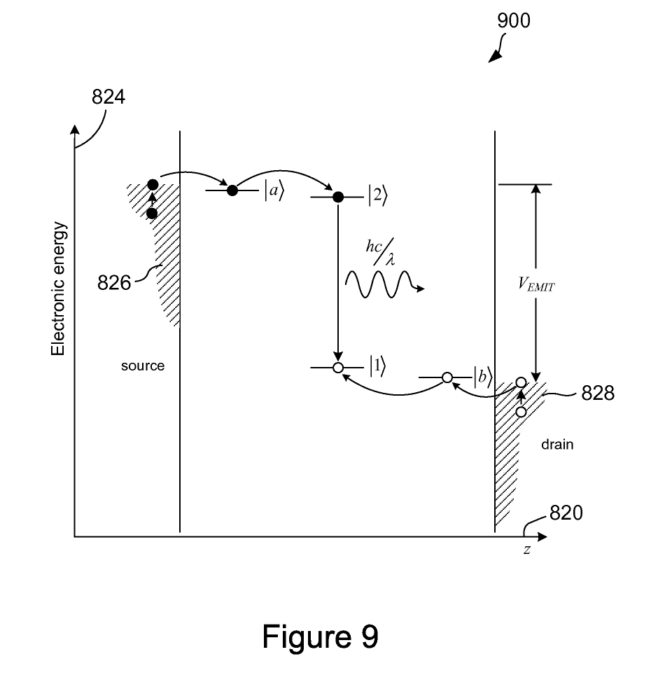

FIG. 9 shows a plot of an electronic energy band diagram 900 associated with applying V_{EMIT} of an appropriate magnitude to the device 800 in accordance with embodiments of the present invention. The band diagram 900 reveals the affect V_{EMIT} of an appropriate magnitude has on the states |a [symbol] and |b [symbol] and on the valence bands 826 and 828. The light-emitting voltage V_{EMIT} raises the electronic energies at the top of the valence band 826 above the state |2 [symbol] and lowers the electronic energies at the top of the valence band 828 below the state |1 [symbol] . The band diagram 900 also reveals that the states |a [symbol] and |2 [symbol] and the states |b [symbol] and |1 [symbol] are detuned. In other words, the state |a [symbol] falls between the top of the valence band 826 and the state |2 [symbol] , and the state |b [symbol] falls between the top of the valence band 828 and the state |1 [symbol] . A light-emitting voltage V_{EMIT} of an appropriate magnitude creates a low energy path for electrons and holes to enter the states |2 [symbol] and |1 [symbol] , respectively. In other words, as shown in the band diagram 900, the state |a [symbol] provides injected electrons with a low energy path from near the top of valence band 826 to the state |2 [symbol] , and the energy of the state |b [symbol] provides injected holes with a low energy path from near the top of the valence band 828 to the state |1 [symbol] .

Note that the semiconductor materials composing the layers 806 and 808 are selected so that states other than states |a [symbol] and |b [symbol] are not available to provide a different path for electrons and holes to leave the states |2 [symbol] and |1 [symbol] . In other words, the states |a [symbol] and |b [symbol] are selected so that when the light-emitting voltage V_{EMIT} is applied, the states |2 [symbol] and |1 [symbol] are isolated, and electrons become trapped in the state |2 [symbol] and holes become trapped in the state |1 [symbol] . Electrons trapped in the state |2 [symbol] can then spontaneously recombine with holes trapped in the state |1 [symbol] emitting photons satisfying the condition:

$${E}_{\vert 2 〉} - {E}_{\vert 1 〉} = \frac{h c}{λ}$$

where h is Planck's constant, c is the speed of light in free space, and λ is the wavelength of a photon emitted as a result of a spontaneous |2 [symbol] →|1 [symbol] transition.

The emission of the device 800 can be stopped when V_{EMIT} is terminated and electrons and holes are swept out of the respective states |2 [symbol] and |1 [symbol] . This can be accomplished by applying an appropriate light-quenching voltage V_{QUENCH} that repositions the states |a [symbol] and |b [symbol] so that electrons and holes have a low energy path from the states |2 [symbol] and |1 [symbol] back to the first and second electrodes 810 and 812 without spontaneously combining in the LEL 804. The light-quenching voltage V_{QUENCH} is also a reverse bias but of a lower magnitude than V_{EMIT}.

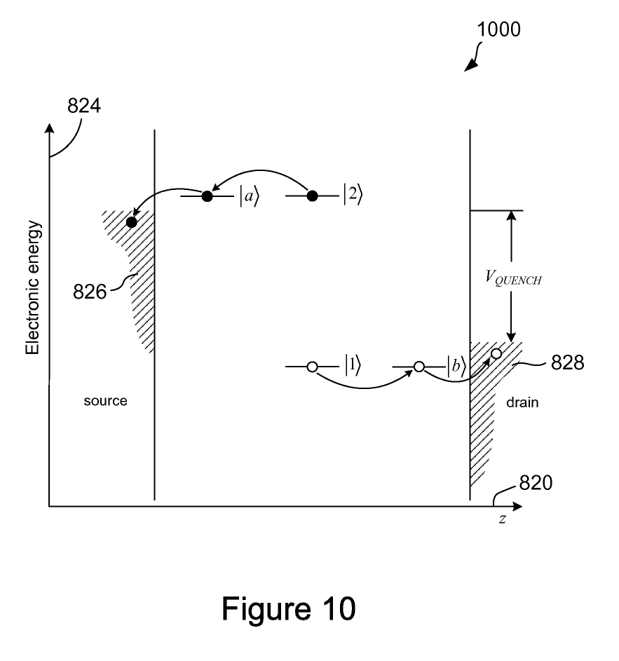

FIG. 10 shows a plot of an electronic energy band diagram 1000 associated with applying V_{QUENCH} of appropriate magnitudes to the device 800 in accordance with embodiments of the present invention. As shown in the example band diagram 1000, the magnitude of the light-quenching voltage V_{QUENCH} is selected to place the state |a [symbol] at an energy below or approximately equal to the state |2 [symbol] and places states near the top of the valence band 826 below the state |a [symbol] . In addition, V_{QUENCH} places the state |b [symbol] above or approximately equal to the state |1 [symbol] and places states near the top of the valence band 828 above the state |b [symbol] . The relative energies of the states under V_{QUENCH} provides a low energy path for electrons to quickly return to the first electrode 810 and a low energy path for holes to quickly return to the second electrode 812. The light-quenching voltage V_{QUENCH} enables fast recovery of energy associated with the injected carriers by returning the carriers to their respective electrodes with little energy loss.

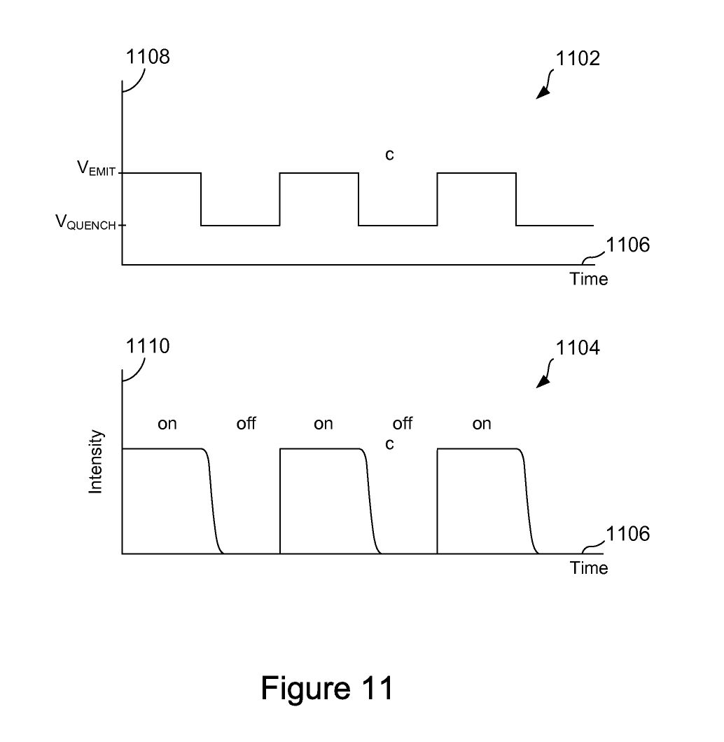

The following is a general description of operating the device 800 to generated modulated light in accordance with embodiments of the present invention. The device 800 may provide modulation rates exceeding 10 Gbits/sec. FIG. 11 shows two plots 1102 and 1104 associated with operating the device 800 in accordance with embodiments of the present invention. Horizontal axes 1106 represent time, vertical axis 1108 represents the magnitude of V_{EMIT} and V_{QUENCH} applied to the device 800, and vertical axis 1110 represents the intensity of light emitted from the device 800. The first plot 1102 shows a pattern of V_{EMIT} and V_{QUENCH} applied to the device 800 versus time. In certain embodiments, V_{EMIT} and V_{QUENCH} can correspond, for example, to the bits “1” and “0,” respectively. The plot 1104 shows “on” and “off” intensity portions of a modulated optical signal emitted from the device 800 versus time. The “on” and “off” portions can also correspond to the bits “1” and “0,” respectively. Plots 1102 and 1104 show that during the time periods when the voltage V_{EMIT} is applied, the device 800 emits light with substantially constant intensity. On the other hand, the plots 1102 and 1104 reveal that during the time intervals when V_{QUENCH} is applied, the intensity of the light emitted rapidly drops off because electrons and holes are quickly swept out of the corresponding states |2 [symbol] and |1 [symbol] , as described above with reference to FIG. 10. Thus, high and low intensity portions of the optical signal shown in plot 1104 can be distinguished.

In FIG. 11, V_{QUENCH} is shown as being applied during the entire time that V_{EMIT} is not applied to the device 800. In practice, however, V_{QUENCH} may only need to be applied long enough to sweep electrons and holes from the respective states |2 [symbol] and |1 [symbol] . Thus, in other embodiments, the duration of V_{QUENCH} needed may be only a fraction of the duration shown in FIG. 11.

The foregoing description, for purposes of explanation, used specific nomenclature to provide a thorough understanding of the invention. However, it will be apparent to one skilled in the art that the specific details are not required in order to practice the invention. The foregoing descriptions of specific embodiments of the present invention are presented for purposes of illustration and description. They are not intended to be exhaustive of or to limit the invention to the precise forms disclosed. Obviously, many modifications and variations are possible in view of the above teachings. The embodiments are shown and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents:

1. A light-emitting device comprising:
a light-emitting layer having a first electronic energy state and a relatively higher energy second electronic energy state;
a first layer disposed adjacent to the light-emitting layer, the first layer having a third electronic energy state relatively lower in energy than the second electronic energy state; and
a second layer disposed adjacent to the light-emitting layer opposite the first layer, the second layer having a fourth electronic energy state relatively higher in energy than the first electronic energy state, wherein when a light-emitting voltage is applied to the light-emitting device, the third and fourth electronic energy states shift so that electrons can combine with holes in the light-emitting layer and light is emitted, and wherein when a light-quenching voltage is applied to the light-emitting device, the energies of the third and fourth electronic energy states shift to prevent electrons from combining with holes in the light-emitting layer.

2. The device of claim 1 further comprising a first electronically conducting metal electrode disposed on the first layer and a second electrode disposed on the second layer, wherein the second electrode comprises an electronically conducting metal, indium tin-oxide, or another suitable conducting substantially transparent material.

3. The device of claim 1 wherein the light-emitting voltage places the third electronic energy state at a relatively higher energy than the second electronic energy state and the fourth electronic energy state at a relatively lower energy than the first electronic energy state so that electrons can be injected into the second electronic energy state and holes can be injected into the first electronic energy state.

4. The device of claim 1 wherein the light emitted results from electrons in the second electronic energy state combining with holes in the first electronic energy state.

5. The device of claim 1 wherein the light emitted is composed of photons having energy substantially equal to the difference between the energy of the first and second electronic energy states.

6. The device of claim 1 wherein the light-quenching voltage places the third electronic energy state at approximately the same energy as the second electronic energy state and the fourth electronic energy state at approximately the same electronic energy as the first electronic energy state so that electrons and holes can be swept from the second electronic energy state and the first electronic energy state, respectively.

7. The device of claim 1 wherein the light-quenching voltage further comprises stopping the emission of light from the light-emitting layer.

8. The device of claim 1 wherein the light-emitting layer further comprises one of:
a quantum well; and
quantum dots embedded in a matrix.

9. The device of claim 8 wherein the matrix further comprises a transparent dielectric material.

10. The device of claim 1 wherein the third electronic energy state further comprises a single electronic energy state that lies within the electronic band gap of the first layer, and the fourth electronic energy state further comprises a single electronic energy state that lies within the electronic band gap of the third layer.

11. The device of claim 1 wherein the first layer further comprises a heavily doped p-type semiconductor and the second layer further comprises a heavily doped n-type semiconductor.

12. The device of claim 11 wherein the third electronic energy state lies near the top of the valence band of the first layer, and the fourth electronic energy state lies near the top of the valence band second layer.

13. The device of claim 1 wherein the first layer and the second layer have electronic band gaps that are larger than the electronic band gap of the light-emitting layer.

14. The device of claim 1 wherein the first layer and the second layer are composed of either the same semiconductor material or different semiconductor materials.

15. A modulatable light source configured in accordance with claim 1 and having a modulation rate greater than 10 Gbits/sec.
